(19) United States
(12) Patent Application Publication
(10) Pub. No.: US 2006/0192216 A1
(43) Pub. Date: Aug. 31, 2006

(54) Semiconductor light emitting device and surface light emitting device

(76) Inventor: Reiji Ono, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/359,396

(22) Filed: Feb. 23, 2006

(30) Foreign Application Priority Data
Feb. 24, 2005 (JP) 2005-048870

(51) Int. Cl. H01L 33/00

(52) U.S. Cl. 257/88

(57) ABSTRACT

A semiconductor light emitting device may include a first supporting member having a main surface; a semiconductor light emitting element having a light emitting layer and provided on the main surface of the first supporting member, the light emitting layer being substantially parallel to the main surface of the first supporting member; and a second supporting member provided on the main surface of the first supporting member, the second supporting member having a reflective surface and a front opening, the reflective surface being configured to reflect light emitted from the semiconductor light emitting element. A sealing resin is provided in a space surrounded by the first supporting member and the second supporting member and configured to seal the semiconductor light emitting element.

### CROSS REFERENCE TO RELATED APPLICATION

This application is based upon and claims the benefit of priority from Japanese Patent Application No. 2005-748870, filed on Feb. 24, 2005, the entire contents of which are incorporated herein by reference.

### BACKGROUND OF THE INVENTION

In a surface light emitting device, such as a liquid crystal display device, light emitted from a light emitting device having a LED chip, is emitted into an optical guide plate made of a transparent material, such as an acrylic resin.

In case light emitted from the upper surface of the LED chip is used as a light source of the surface light emitting device, a side length of the LED chip will be enlarged, such as 1 mm or more, in order to obtain a high optical output. If the area of the LED chip is enlarged, the height of the LED chip from a mounting surface to the top of the LED chip may be greater than the thickness of the optical guide layer (about 0.5-2.0 mm). In other words, the size of a light beam from the LED chip may be greater than the optical guide plate thickness. As a result, it may be difficult to efficiently introduce light emitted from the LED chip into the optical guide plate.

### SUMMARY

In one aspect of the present invention, there is provided a semiconductor light emitting device, comprising: a first supporting member having a main surface; a semiconductor light emitting element having a light emitting layer and provided on the main surface of the first supporting member, the light emitting layer being substantially parallel to the main surface of the first supporting member; a semiconductor light emitting element having a light emitting layer and provided on the main surface of the first supporting member, the light emitting layer being substantially parallel to the main surface of the first supporting member; a second supporting member provided on the main surface of the first supporting member, the second supporting member having a reflective surface and a front opening, the reflective surface being configured to face side portions of the light emitting element to reflect light emitted from the semiconductor light emitting element, the front opening being configured for light both directly emitted from the semiconductor light emitting element and reflected from the reflective surface to be emitted there through, the semiconductor light emitting element being provided in a region surrounded by the reflective surface and the front opening; a sealing resin provided in a space surrounded by the first supporting member and the second supporting member and configured to seal the semiconductor light emitting element; wherein the semiconductor light emitting element has a predetermined cross-sectional shape and is oriented at a predetermined angle relative to the front opening to achieve a desired emission of light from the semiconductor light emitting device.

In another aspect of the present invention, there is provided a semiconductor light emitting device, comprising: a first supporting member having a main surface; a semiconductor light emitting element having a light emitting layer and provided on the main surface of the first supporting member, the light emitting layer being substantially parallel to the main surface of the first supporting member; a second supporting member provided on the main surface of the first supporting member, the second supporting member having a reflective surface and a front opening, the reflective surface being configured to face side portions of the light emitting element to reflect light emitted from the semiconductor light emitting element, the front opening being configured for light both directly emitted from the semiconductor light emitting element and reflected from the reflective surface to be emitted there through, the semiconductor light emitting element being provided in a region surrounded by the reflective surface and the front opening; a sealing resin provided in a space surrounded by the first supporting member and the second supporting member and configured to seal the semiconductor light emitting element; wherein an upper surface of the second supporting member is a mounting surface for mounting the semiconductor light emitting device to other apparatus to provide lighting.

### BRIEF DESCRIPTIONS OF THE DRAWINGS

FIG. 1 is a perspective view of a semiconductor light emitting device in accordance with a first embodiment of the present invention.

FIG. 2 is a plan view of the semiconductor light emitting device in accordance with the first embodiment.

FIG. 3 is a plan view of a semiconductor light emitting device showing an LED chip mount surface in accordance with the first embodiment.

FIG. 4 is an electrode pattern of a flip-chip bonding type LED chip in accordance with the first embodiment.

FIGS. 5-6 are cross-sectional views of LED chips in accordance with the first embodiment.

FIG. 7 is a graph showing directivity (radiation pattern) of the LED chip shown in FIG. 5.

FIG. 8 is a graph showing directivity on an X-Z plane of the semiconductor light emitting device on which the LED chip shown in FIG. 5 is mounted.

FIG. 9 is a graph showing directivity on an X-Y plane of the semiconductor light emitting device on which the LED chip shown in FIG. 5 is mounted.

FIG. 10 is a graph showing directivity (radiation pattern) of the LED chip shown in FIG. 6.

FIG. 11 is a graph showing directivity on an X-Z plane of the semiconductor light emitting device on which the LED chip shown in FIG. 6 is mounted.

FIG. 12 is a cross-sectional view of a surface light emitting device in accordance with the first embodiment of the present invention.

FIG. 13 is a plan view of the surface light emitting device shown in FIG. 12.

FIG. 14 is a cross-sectional view of a semiconductor light emitting device in accordance with a comparative example.

FIG. 15 is a plan view of a liquid crystal display having the semiconductor light emitting device in accordance with the first embodiment of the present invention.

FIG. 16 is a perspective view of a semiconductor light emitting device in accordance with a modification of the first embodiment of the present invention.

FIG. 17 is a plan view of the semiconductor light emitting device shown in FIG. 16.

FIG. 18 is a perspective view of a semiconductor light emitting device in accordance with a second embodiment of the present invention.

FIG. 19 is a plan view of a semiconductor light emitting device in accordance with a third embodiment of the present invention.

FIG. 20 is a graph showing directivity of the semiconductor light emitting device in accordance with the third embodiment.

FIG. 21 is a perspective view of a semiconductor light emitting device in accordance with a fourth embodiment of the present invention.

FIG. 22 is a graph showing directivity of the semiconductor light emitting device in accordance with the fourth embodiment.

FIG. 23 is a cross-sectional view of a surface light emitting device in accordance with the fourth embodiment of the present invention.

FIG. 24 is a plan view of a surface light emitting device in accordance with the fourth embodiment of the present invention.

FIG. 25 is a perspective view of a semiconductor light emitting device in accordance with a fifth embodiment of the present invention.

FIG. 26 is a cross-sectional view of a semiconductor light emitting device in accordance with a sixth embodiment of the present invention.

FIG. 27 is a cross-sectional view showing a manufacturing process of a semiconductor light emitting device in accordance with the sixth embodiment.

### DETAILED DESCRIPTION OF THE INVENTION

Various connections between elements are hereinafter described. It is noted that these connections are illustrated in general and, unless specified otherwise, may be direct or indirect and that this specification is not intended to be limiting in this respect.

In the following descriptions of the embodiments described herein, terms such as horizontal, vertical, upward, and downward are used to describe orientation and direction. However, such terms are only intended to be used in a relative sense in conjunction with the figures and not in an absolute sense that requires a particular orientation for mounting or use of any device disclosed herein.

Embodiments of the present invention will be explained with reference to the drawings as follows.

### First Embodiment

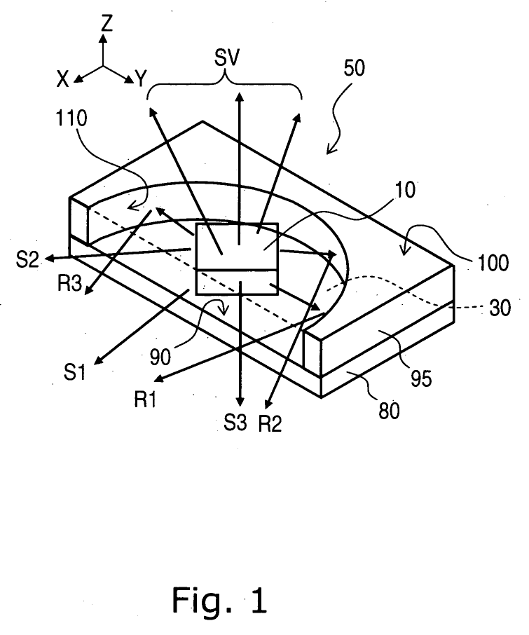

A first embodiment of the present invention will be explained hereinafter with reference to FIGS. 1-13.

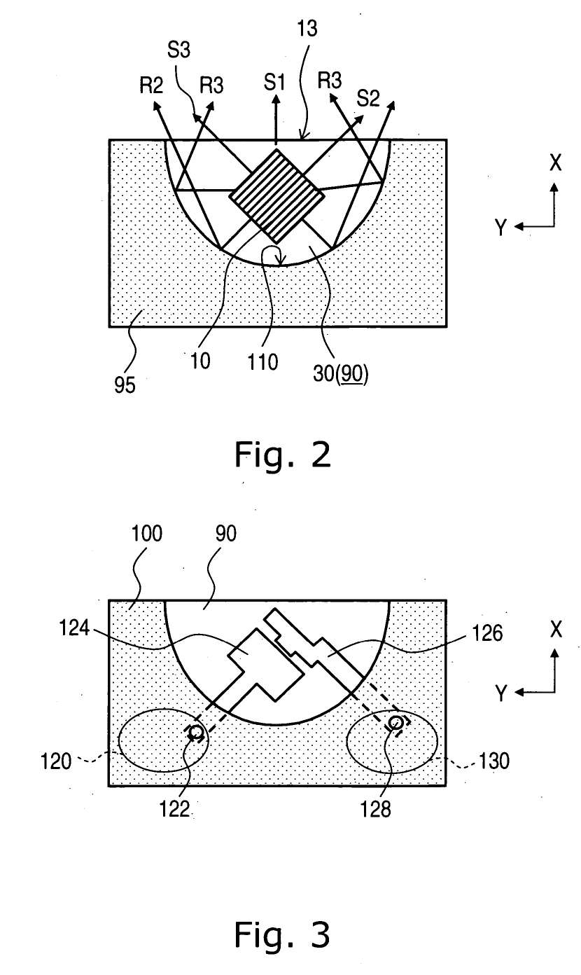

FIG. 1 is a perspective view of a semiconductor light emitting device 50 in accordance with a first embodiment of the present invention. FIG. 2 is a plan view of the semiconductor light emitting device 50 in accordance with the first embodiment.

In the semiconductor light emitting device 50, an LED chip 10 is mounted on an upper surface 90 of a first supporting member 80. The LED chip 10 is mounted by flip chip bonding and electrically connected by wire (not shown in FIG. 1). The LED chip 10 has laminated semiconductor layers including an active layer. The active layer of the LED chip 10 is substantially parallel to the upper surface 90 of the first supporting member 80. In this embodiment, substantially parallel may be defined consistent with use of that terminology in the semiconductor industry. Thus, the active layer is substantially parallel to the upper surface 90 of the first supporting member 80, even when the active layer is slanted by an uneven adhesive or uneven upper surface 90 of the first supporting member 80.

A constituent part of light emitted from the LED chip 10 is parallel to the active layer.

A second supporting member 95 is provided on the first supporting member 80. The second supporting member 95 partially surrounds the LED chip 10.

The first supporting member 80 and the second supporting member 95 may be made of, for example, ceramics, an organic material, a metal or the like. The first supporting member 80 and the second supporting member 95 may be adhered, for example, by a silver solder.

As shown in FIG. 2, the second supporting member 95 has a reflective surface 110 and an opening 13. The reflective surface 110 faces the LED chip 10 and functions to reflect light emitted from the LED chip 10. The light and the reflected light are emitted through the opening 13 of the second supporting member 95. In the semiconductor light emitting device 50, the reflective surface 110 is substantially perpendicular to the upper surface 90 of the first supporting member 80, wherein substantially perpendicular may be defined consistent with the use of that terminology in the semiconductor industry, for reasons such as described above regarding “substantially” parallel.

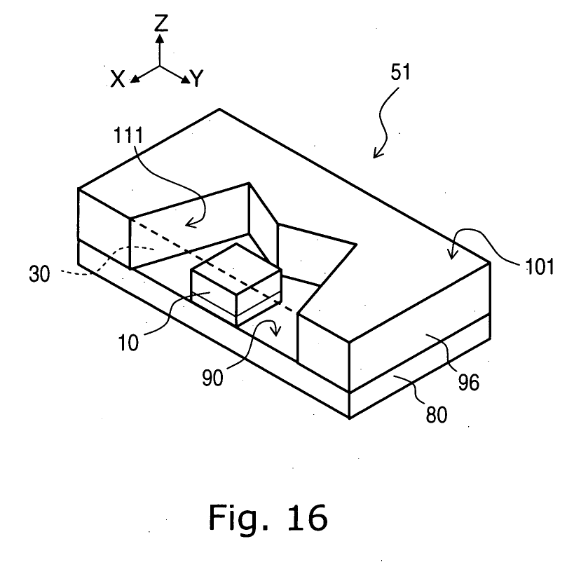

As shown in FIG. 2, in a plan view, the reflective surface 110 has a substantially semicircular shape. However, the reflective surface 110 may have a semi-elliptical shape, a parabolic shape or other shape effective to reflect the light emitted by the LED chip 10 through the opening 13 in a desired manner which may or may not be symmetric. The reflective surface 110 may include flat surfaces that meet at predetermined angles such as, for example, shown in FIG. 16 which is more fully described below.

As also shown in FIG. 2, the LED chip 10 can be set back, i.e., spaced away from an edge of first supporting member 30 that defines a front of the opening 13.

A sealing resin 30 may be provided on the LED chip 10 and in a space surrounded by the first supporting member 80 and the second supporting member 95. The sealing resin 30 is preferably transparent to light emitted from the LED chip 10.

A direction of light emitted from the semiconductor light emitting device 50 is explained. As shown by arrows S1, S2, S3, R2 and R3 in FIGS. 1-2, light is emitted from the LED chip 10 to a horizontal direction, which is parallel to an X-Y plane depicted in FIG. 2. Light represented by arrows S1, S2 and S3 is emitted from the LED chip 10 directly through the opening 13. Light represented by arrows R2 and R3 is emitted from the LED chip 10 to the reflective surface 110, reflected by the surface 110 and emitted through the opening 13. Light emitted in directions including a vertical, or Z-direction, component, as depicted in FIG. 1, depends on a directivity of the LED chip 10. Depending on the vertical component, such light may not be reflected by reflective surface 110. The light emitted with a vertical component is shown by arrows SV in FIG. 1.

In this embodiment, the LED chip 10 has a square shape in plan view, i.e., a square cross section, and is oriented such that each side is angled 45 degree relative to the opening 13. As a result, wide-angle light may be emitted from the semiconductor light emitting device 50, since light represented by the arrows S2, S3 or the like, which has a large emission angle, is emitted directly from the LED chip 10. Thus wide-angle light with uniform luminous intensity may be obtained. In this regard, for this example of the LED chip 10 having a square cross section and the reflective surface 110 having a semicircular shape, the 45 degree orientation of the LED chip 10 may represent an optimum orientation.

While a 45 degree orientation is shown for the square-shaped LED 10 shown in FIG. 1, other orientations are possible. The orientation angle can be chosen to optimize the amount of and uniformity of light intensity, or a predetermined nonuniform intensity, based on the shape of the LED chip 10, which need not be square in cross section, and the shape of the reflective surface 110.

FIG. 3 is a plan view of a semiconductor light emitting device showing an LED chip mount surface in accordance with the first embodiment

On the upper surface 90 of the first supporting member 80, an electrode pattern 124, which is connected to a cathode of the LED chip 10, and an electrode pattern 126, which is connected to an anode of the LED chip 10, are provided. Through holes 122 and 128 are provided in the second supporting member 95. Connecting portions 120 and 130, which are for supplying operating voltage to drive the LED chip 10, are provided on an upper surface 100 of the second supporting member 95. Conductive elements, e.g., conductive metal, not shown, are provided in through holes 122 and 128 to connect electrode patterns 124 and 126 to connecting portions 120 and 130, respectively.

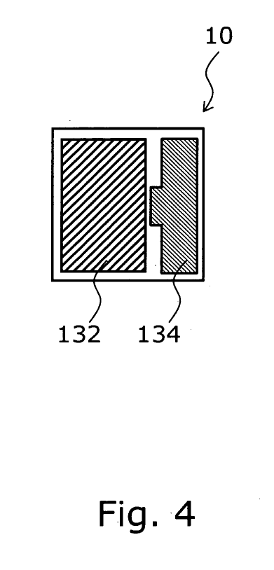

FIG. 4 is an electrode pattern of a flip-chip bonding type LED chip in accordance with the first embodiment. An anode electrode 134 and a cathode electrode 132 are provided on a bottom surface of the LED chip 10. The anode electrode 134 and the cathode electrode 132 are electrically connected to the electrode patterns 124 and 126, respectively, by the flip-chip bonding.

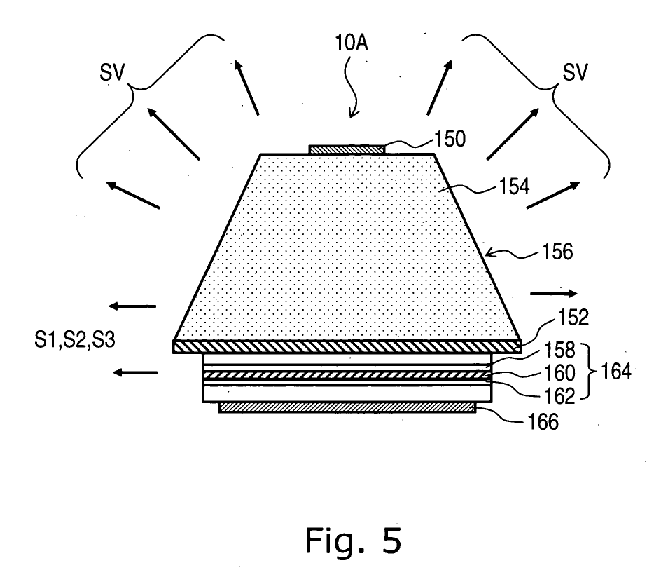

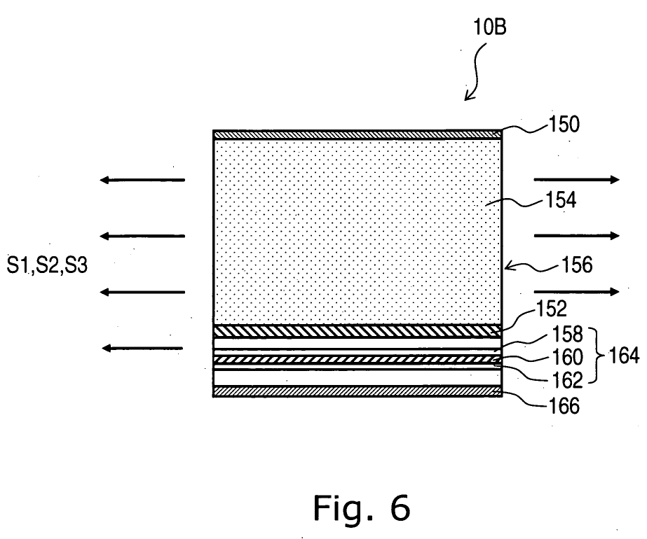

Alternatively, an electrode of the LED chip 10 may be not provided for flip-chip bonding. Electrodes may be provided on opposite surfaces of the LED chip 10 as shown in FIGS. 5-6. In this case, a wire may be connected from one electrode to one of the connecting portions 124 and 126.

As shown in FIG. 5, an LED chip 10A has a substrate 154 and a semiconductor laminated structure 164. The semiconductor laminated structure 164 may include, for example, an InGaAlP active layer 160 (thickness about 500-600 nm) and InGaAlP clad layers 158, 162. The substrate 154 may be a GaP substrate, which is substantially transparent to light emitted from the active layer 160. Electrodes 166 and 150 are provided on a bottom surface of the semiconductor laminated structure 164 and an upper surface of the substrate 154, respectively. A side surface of the substrate 156 is slanted such that the upper surface of the substrate 154 is smaller in area than the bottom surface of the substrate 154. The amount of the light SV emitted by the LED chip 10A is increased by slanting the side surface 156 of the substrate 154.

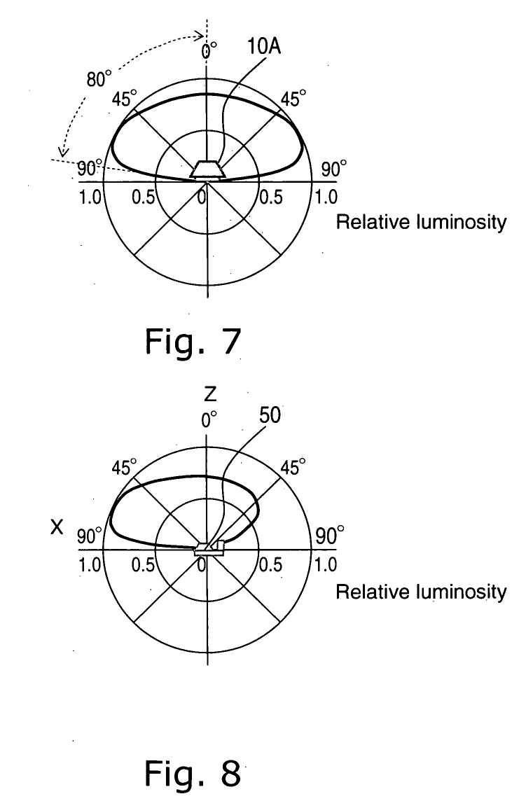

A radiation pattern of the LED chip 10A shown in FIG. 5 is explained with reference to FIG. 7, which is a graph showing directivity (radiation pattern) of the LED chip 10A shown in FIG. 5. In FIG. 7, relative luminosity is shown relative to a vertical cross section of the LED chip 10A. An angle where the luminosity is one-half of the maximum (half angle θ_{1/2}), is about 80 degrees. As a result, a wide-angle uniform luminosity distribution in a vertical direction is obtained.

FIG. 8 is a graph showing directivity on an X-Z plane of the semiconductor light emitting device 50 on which the LED chip 10A is mounted. An optical output toward the X-axis or toward the opening 13 is increased, since the reflective surface 110 functions to reflect the light emitted by the LED chip 10A. As a result, the directivity is distorted to a front side (X-axis).

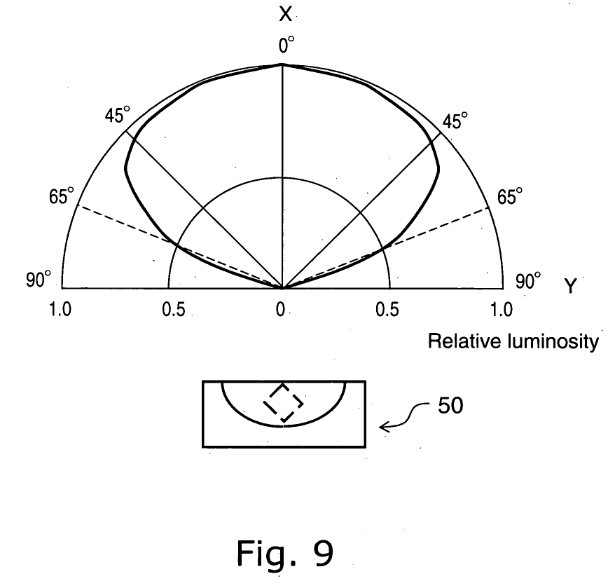

FIG. 9 is a graph showing directivity on an X-Y plane of the semiconductor light emitting device on which the LED chip 10A is mounted. A half angle θ_{1/2} is about 65 degree. As a result, light having wide-angle directivity is obtained.

Another example of the LED chip 10 is explained with reference to FIG. 6. As shown in FIG. 6, in an LED chip 10B, the side surface of the substrate 154 is substantially perpendicular to the main surface of the substrate 154. The upper surface of the substrate 154 is covered with the electrode 150, which is made of a reflective metal. Light represented by the arrows S1, S2, S3, which is emitted from the side surface 156, is increased.

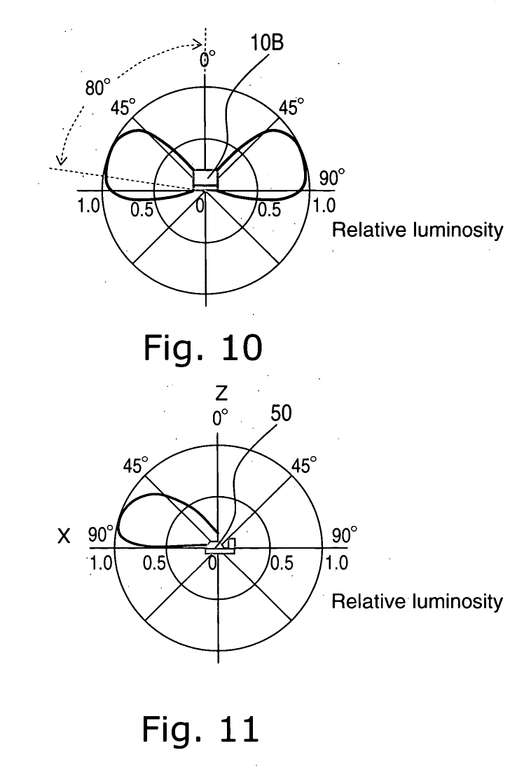

FIG. 10 shows a radiation pattern of the LED chip 10B. As shown in FIG. 10, light emitted toward the horizontal direction is stronger than light emitted toward the vertical direction.

FIG. 11 is a graph showing directivity on an X-Z plane of the semiconductor light emitting device 50 on which the LED chip 10B is mounted. As shown in FIG. 11, an optical output toward the X-axis or toward the opening 13 is. increased, since the reflective surface 110 functions to reflect the light emitted by the LED chip 10B. As a result, the directivity is distorted to a front side (X-axis).

Directivity on an X-Y plane of the semiconductor light emitting device 50 on which the LED chip 10B is mounted, is similar to that shown in FIG. 9, so further explanation of such directivity is omitted.

Structures explained with reference to FIGS. 5-6 are examples implementing the LED chip 10. Other types of LEDs such as InGaN based semiconductors emitting 380-570 nm wavelength light, may be used as the LED chip 10 to obtain ultraviolet to yellow light. A fluorescent material such as phosphors may be dispersed in the sealing resin 30 to obtain white light.

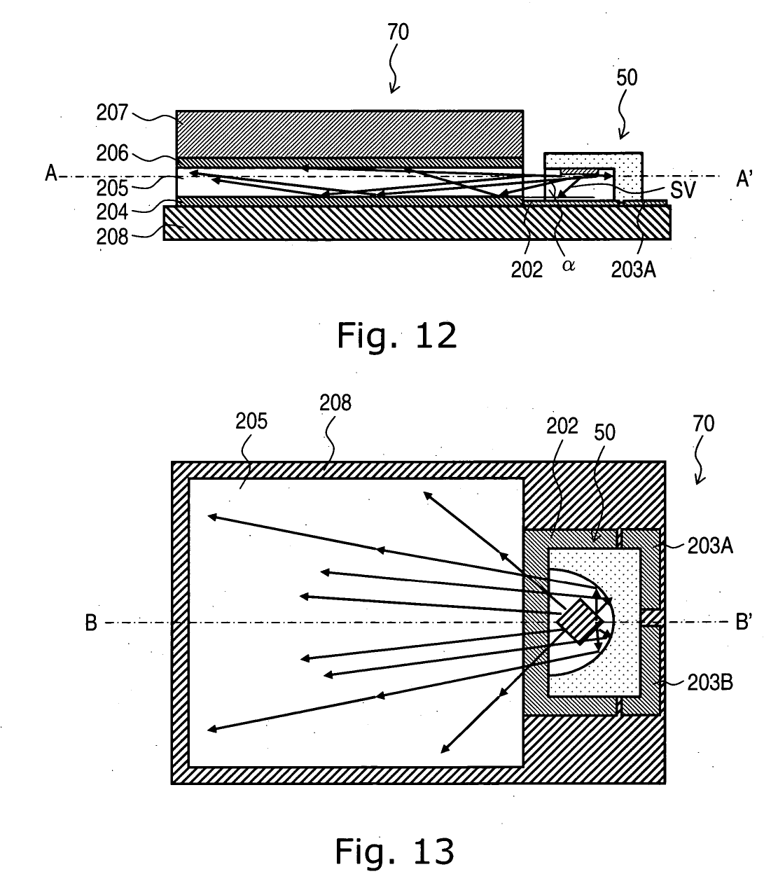

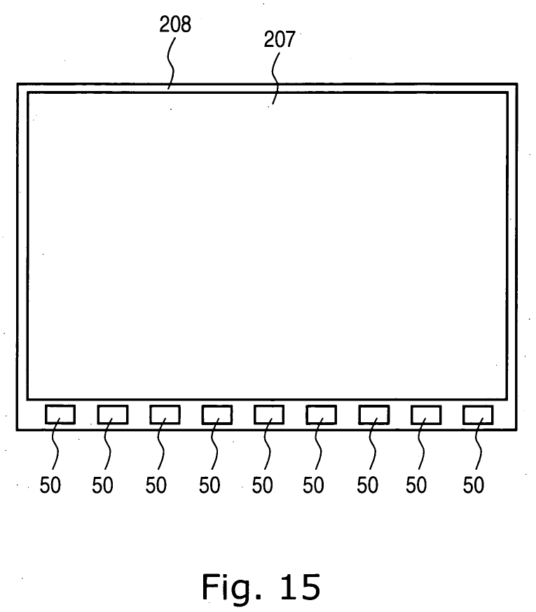

A surface light emitting device 70 having the semiconductor light emitting device 50 is explained next. FIG. 12 is a cross-sectional view of the surface light emitting device 70 taken along line B-B of FIG. 13, in accordance with the first embodiment of the present invention. FIG. 13 is a plan view of the surface light emitting device 70 taken along line A-A′ of FIG. 12. FIG. 15 is a plan view of a liquid crystal display having semiconductor light emitting devices 50, in accordance with the first embodiment of the present invention, to provide light to the display.

The surface light emitting device 70 has the semiconductor light emitting device 50, a mounting board 208, a reflection layer 202, a reflection board 204, a light guide plate 205, a diffusion plate 206 and a liquid crystal displaying part 207. Electrodes 203A and 203B are provided on the mounting board 208. The semiconductor light emitting device 50 is mounted on the electrodes 203A and 203B with the bottom surface of the first supporting member 80 facing upward. The connecting portions 120 and 130 on the upper surface 100 of the second supporting member 95 of the semiconductor light emitting device 50 are connected to the electrodes 203A and 203B, respectively, and electric power is supplied to the semiconductor light emitting device 50 through electrodes 203A and 203B.

The reflection layer 202 is provided on the mount board 208 near the semiconductor light emitting device 50. The reflection layer 202 may be connected to the electrode 203A or 203B. The reflection layer 202 reflects light SV toward the light guide plate 205 or the diffusion plate 206.

The reflection plate 204, the light guide plate 205, the diffusion plate 206, and the liquid crystal displaying part 207 are mounted on the mount board 208 in this order. The reflection plate 204 reflects light toward the light guide plate 205. The light guide plate 205 guides light emitted from the semiconductor light emitting device 50 and spreads light vertically and horizontally. The diffusion board 206 functions to diffuse light emitted from the light guide plate 205. A uniform light is emitted from the diffusion board 206.

Light having directivity such as shown in FIGS. 7-11 is emitted from the semiconductor light emitting device 50 and enters into the side (right side in FIG. 12) of the light guide plate 205. Light angled upward in FIG. 12 enters into the diffusion plate 206 directly, is uniformly diffused and enters the liquid crystal displaying part 207.

Light angled downward in FIG. 12 from the semiconductor light emitting device 50, enters the light guide plate 205, is reflected by the reflection plate 204 and enters the liquid crystal displaying part 207 via the light guide plate 205 and the diffusion plate 206. In case an irradiation angle a (FIG. 12) of light emitted from the semiconductor light emitting device 50 is small, the light reflected by the reflection plate 204 does not enter the diffusion plate 206 and is emitted from a side (left side in FIG. 12) of the light guide plate 205.

Optionally, a surface of the reflection plate 204 may be provided with a plurality of protrusions and/or depressions in order to diffuse reflected light that enters the diffusion plate 206.

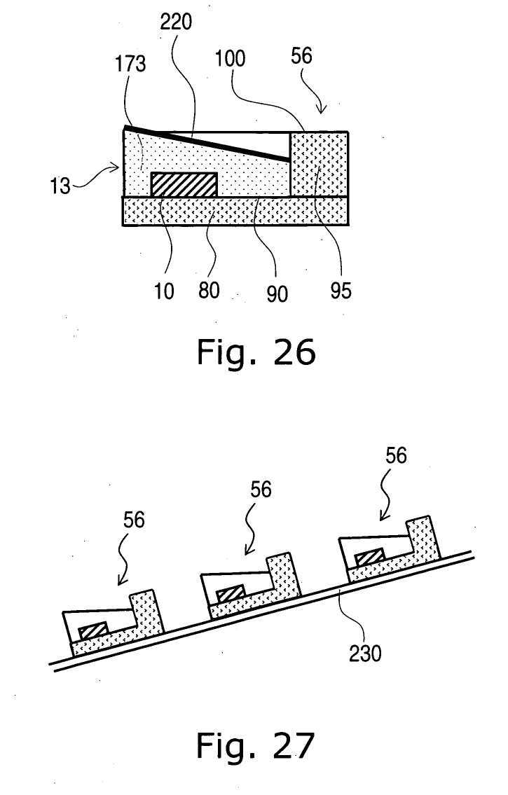

By providing the reflection layer 202, light entering the liquid crystal displaying part 207 is increased. As a result, light efficiency may be improved. However, the reflection layer 202 need not be provided on the mount board 208. Instead, a reflection layer may be provided in the semiconductor light emitting device 50. The reflection layer in the semiconductor light emitting device 50 may be provided on the sealing resin 30 as shown in FIG. 26, as described more fully below. The reflection layer may be a metal or a dielectric layer formed by sputtering.

In this embodiment, the semiconductor light emitting device 50 is mounted on the mount board 208 with the bottom surface of the first supporting member 80 facing upward. A height of the LED chip 10 from the mount board 208 is changeable by changing a height of the second supporting member 95.

It is also possible to provide the semiconductor light emitting device 50 in a suitable position so that light is emitted to the light guide plate 205 efficiently.

A surface light emitting device may be used not only for a back light for a liquid crystal display or key buttons but also for general lighting.

### COMPARATIVE EXAMPLE

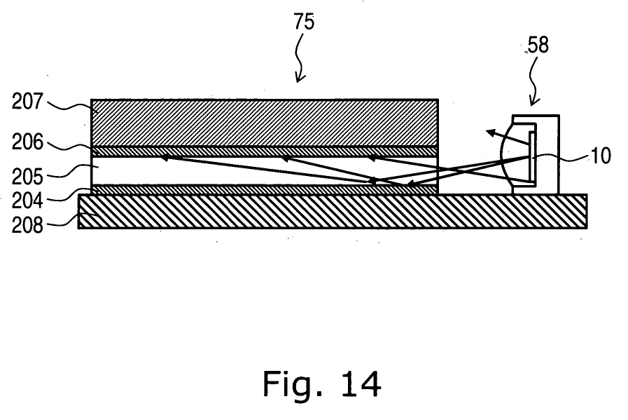

A comparative example considered by the inventors is explained with reference to FIG. 14. A semiconductor light emitting device 58 and a surface light emitting device 75 are described in accordance with the comparative example. With respect to each portion of this comparative example, the same or corresponding portions of the surface light emitting device or the semiconductor light emitting device of the first embodiment shown in FIGS. 1-13 are designated by the same reference numerals, and explanation of such portions is omitted.

In this comparative example, the semiconductor light emitting device 58 has an LED chip 10 which emits a light from an upper surface thereof. The semiconductor light emitting device 58 is mounted on the mounting board 208 such that the upper surface of the LED chip 10 faces to a side of the light guide plate 205.

If the LED chip 10 is enlarged so that its upper surface has a width (vertical height in the chip orientation shown in FIG. 14) to I mm or more in order to obtain high optical output, the width of the LED chip 10 is positioned higher than a thickness of the light guide plate 205, which may typically have a. thickness of about 2 mm. As a result, it is difficult for all of the light emitted from the semiconductor light emitting device 58 to enter the light guide plate 205.

However, by using the semiconductor light emitting device 50 shown in the first embodiment in the surface light emitting device, light having a good directivity is capable of efficiently entering the light guide plate 205.

Further, since light emitting device 50 does not include a reflecting structure on top, its overall height is reduced and it can be mounted on the mount board 208 with the bottom surface of the first supporting member 80 facing upward. As a result, light emitting device 50 can be matched with the height of the light guide plate 205 to efficiently direct light into the light guide plate 205.

### Modification of the First Embodiment

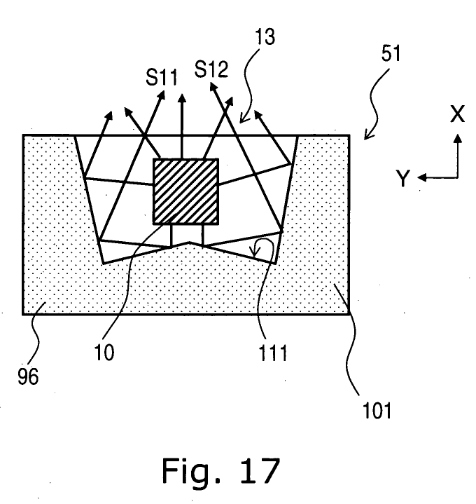

A semiconductor light emitting device 51 in accordance with a modification of the first embodiment of the present invention is described with reference to FIGS. 16 and 17. With respect to each portion of this embodiment, the same or corresponding portions of the semiconductor light emitting device of the first embodiment shown in FIGS. 1-13, 15 are designated by the same reference numerals, and explanation of such portions is omitted.

In the modification of the first embodiment, a reflective surface 111 has a W shape in plan view as shown in FIGS. 16-17. More particularly, a protrusion having an acute angle is provided a on portion of the reflective surface 111 on a back portion of a second supporting member 96. Additionally, the reflective surface 111 consists of plural flat surfaces oriented at predetermined angles to achieve a desired directivity.

As shown in FIG. 17, light represented by arrows S11 and S12 emitted in a back direction, which is opposite to the opening 13, is reflected by the inner surface of the second supporting member 96 and emitted from the reflective surface 111 though the opening 13. The light shielded by the LED chip 10 is reduced by the acute angle protrusion provided on the second supporting member 96.

### Second Embodiment

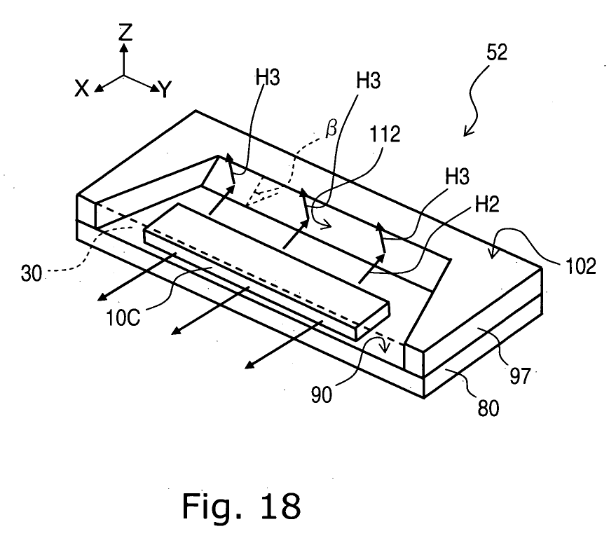

A semiconductor light emitting device 52 in accordance with a second embodiment of the present invention is explained with reference to FIG. 18. With respect to each portion of this embodiment, the same or corresponding portions of the semiconductor light emitting device of the first embodiment or its modification shown in FIGS. 1-13, 15-17 are designated by the same reference numerals, and explanation of such portions is omitted.

In this second embodiment, an LED chip 10C has a rectangular shape with its longitudinal side being parallel to opening 13. The rectangular LED chip 10C is provided in order to obtain large optical output. In such a case in which the rectangular LED chip 10C is provided, a wide emission point along the Y-axis is obtained.

In this second embodiment, a part of a reflective surface 112 is slanted. The slanted portion is provided confronting the back of the LED chip 10C. The slanted portion has a slanted angle β (FIG. 18), which may be set at 0-90 degree. A metal may be coated on the slanted portion and/or the reflective surface 112 in order to obtain a high reflective index.

Light represented by arrows H2 emitted backward is reflected by the slanted portion. Reflected light represented by arrows H3 is emitted upward. A reflector, which reflects light toward opening 13, may be provided on an upper surface of a second supporting member 97.

### Third Embodiment

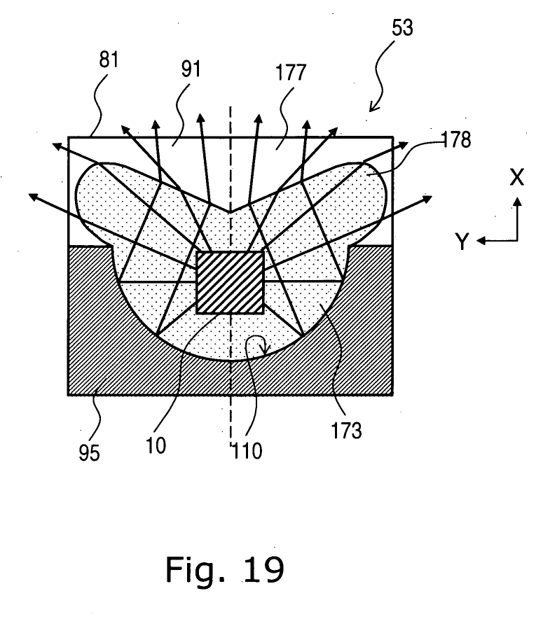

A semiconductor light emitting device 53 in accordance with a third embodiment of the present invention is explained with reference to FIG. 19. With respect to each portion of this embodiment, the same or corresponding portions of the semiconductor light emitting device of the first embodiment, its modification or the second embodiment shown in FIGS. 1-13, 15-18 are designated by the same reference numerals, and explanation of such portions is omitted.

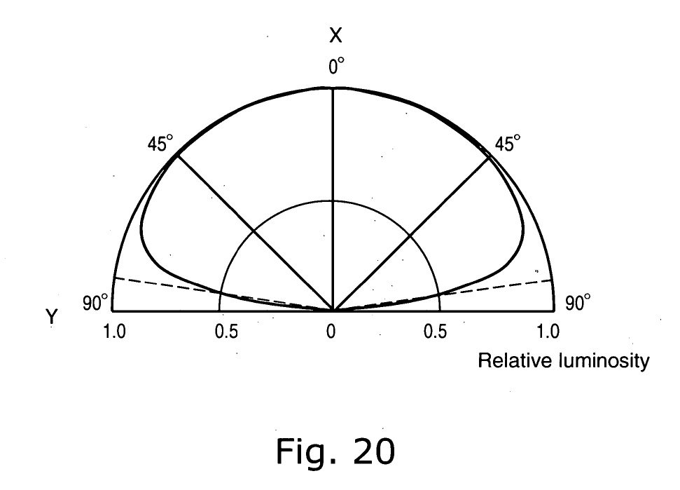

FIG. 19 is a plan view of the semiconductor light emitting device 53 in accordance with the third embodiment of the present invention. FIG. 20 is a graph showing directivity of the semiconductor light emitting device 53.

In this third embodiment, a first supporting member 91, on which LED chip 10 is mounted, extends outward beyond the second supporting member. A sealing resin 173 protrudes outward through the opening 13 in the second supporting member 95 as a protrusion 178. A depression 177 in protrusion 178 is depressed in front of and toward the LED chip 10.

Light emitted from the LED chip 10 toward a front direction (X-axis) is refracted outward by the depression 177 at the interface between the sealing resin 173 and air in the environment. In this manner, the protrusion 178 may be configured to function as a convex lens, in order to effectively disperse light emitted toward the protrusion 178.

A radiation pattern as shown in FIG. 20, in which a half angle is about 80 degree, may be obtained by the semiconductor light emitting device 53.

### Fourth Embodiment

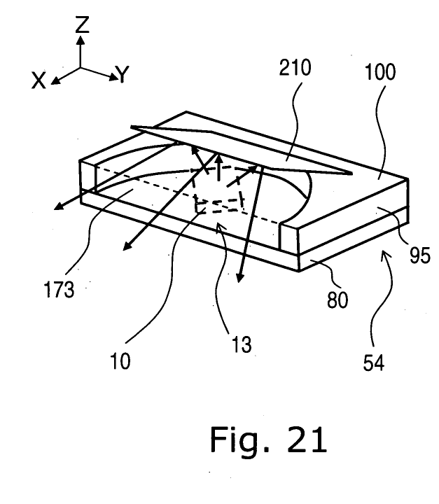

A semiconductor light emitting device 54 in accordance with a fourth embodiment of the present invention is explained with reference to FIGS. 21-24. With respect to each portion of this embodiment, the same or corresponding portions of the semiconductor light emitting device of the first embodiment, its modification or the second or third embodiments shown in FIGS. 1-13, 15-20 are designated by the same reference numerals, and explanation of such portions is omitted.

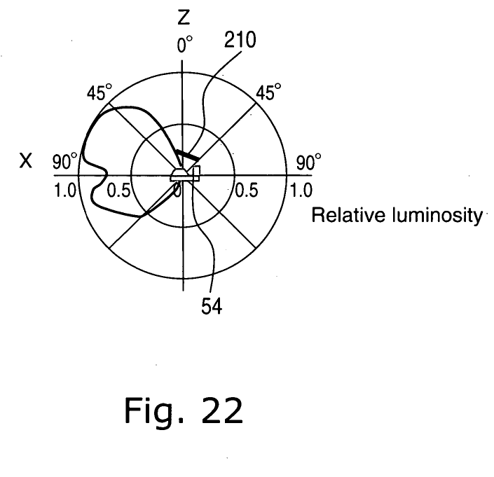

FIG. 21 is a perspective view of the semiconductor light emitting device 54 in accordance with a fourth embodiment. FIG. 22 is a graph showing directivity of the semiconductor light emitting device 54.

The semiconductor light emitting device 54 has a reflection board 210 on the upper surface 100 of the second supporting member 95. The reflection board 210 is slanted with its reflection surface facing opening 13. The reflection board 210 functions as a reflector which reflects light toward the front opening. The directivity of light from the semiconductor light emitting device 54 is changeable by controlling the slanted angle of the reflection board 210. The effect of reflection by the reflection board 210 on the directivity of light emitted from the semiconductor light emitting device 54 is shown in FIG. 22. As seen in comparison to the directivity shown in FIG. 8, substantially no light is directed to the right along the X-axis.

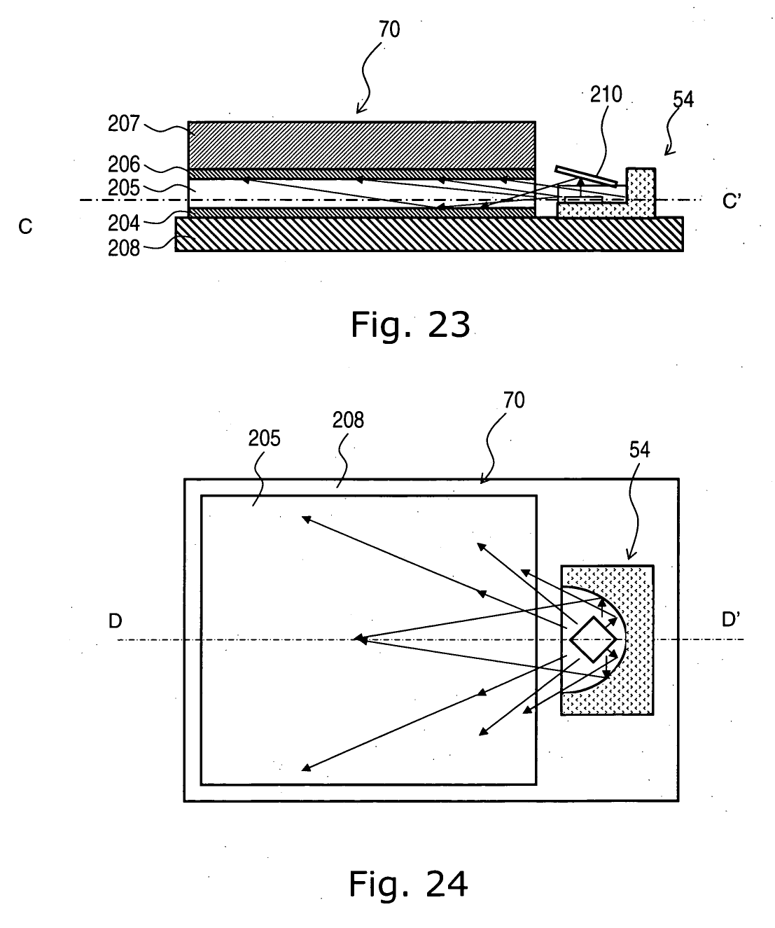

FIG. 23 is a cross-sectional view of a surface light emitting device in accordance with the fourth embodiment. FIG. 24 is a plan view of the surface light emitting device in accordance with the fourth embodiment. FIG. 23 is a cross-sectional view taken along D-D′ line in FIG. 24 and FIG. 24 is a plan view taken along C-C′ line in FIG. 23.

As shown in FIG. 23, the semiconductor light emitting device 54 is mounted on the mounting board 208 with the bottom surface of the first supporting member facing downward. Light emitted from the LED chip 10 is reflected by the reflection board 210 and enters the light guide plate 205. In case the reflection board is slanted about 20 degree, the reflection light from the reflection board 210 may be directed downward and, as a result, light entering into the light guide plate 205 is increased.

### Fifth Embodiment

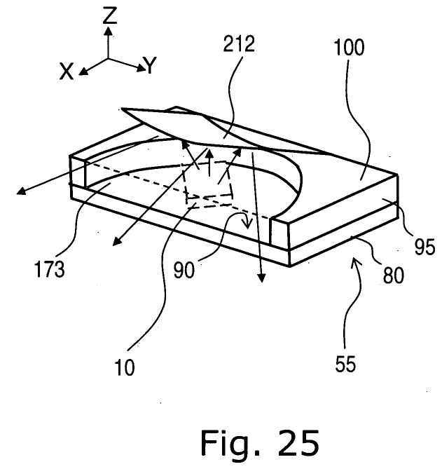

A semiconductor light emitting device 55 in accordance with a fifth embodiment of the present invention is explained with reference to FIG. 25. With respect to each portion of this embodiment, the same or corresponding portions of the semiconductor light emitting device of the first, second, third, fourth embodiment or its modification, shown in FIGS. 1-13, 15-24, are designated by the same reference numerals, and explanation of such portions is omitted.

FIG. 25 is a perspective view of the semiconductor light emitting device 55. In this embodiment, the semiconductor light emitting device 55 has a reflection board 212 which is bent such that a region of the reflection board 212 above the LED chip 10 protrudes toward the LED chip 10 and the upper surface 90 of the first supporting member 88. Also as a result of the bend in the reflective board 212, other regions of the reflection board 212 are at a greater distance from the upper surface 90 of the first supporting member 80 than the region of the reflection board 212 above the LED chip 10. As a result, light having wide directivity may be obtained.

### Sixth Embodiment

A semiconductor light emitting device 56 in accordance with a sixth embodiment of the present invention is explained with reference to FIGS. 26-27. With respect to each portion of this embodiment, the same or corresponding portions of the semiconductor light emitting device of the first, second, third, fourth, fifth embodiment or its modification, shown in FIGS. 1-13, 15-24, are designated by the same reference numerals, and explanation of such portions is omitted.

FIG. 26 is a cross-sectional view of the semiconductor light emitting device 56. In this sixth embodiment, an upper surface of the sealing resin 173 is slanted with an expanding thickness toward the opening 13. A reflection layer 220 is provided on the slanted upper surface of the sealing resin 173. The reflection layer 220 may be made of a metal or a dielectric material. Light emitted from the LED chip 10 is reflected by the reflection layer 220. As a result, light entering the light guide plate 205 is increased. The reflection layer 220 may be bent as shown in FIG. 25.

FIG. 27 is a cross-sectional view showing a manufacturing process of a semiconductor light emitting device in accordance with the sixth embodiment.

In order to form the slanted upper surface of the sealing resin 173, a liquid state sealing resin is applied to the semiconductor light emitting devices 56, when a frame, on which the semiconductor light emitting devices 56 are mounted, is angled. After the sealing resin 173 is cured, a reflection layer 220 is formed such as by sputtering or the like.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor light emitting device, comprising:
a first supporting member having a main surface;
a semiconductor light emitting element having a light emitting layer and provided on the main surface of the first supporting member, the light emitting layer being substantially parallel to the main surface of the first supporting member;
a second supporting member provided on the main surface of the first supporting member, the second supporting member having a reflective surface and a front opening, the reflective surface being configured to face side portions of the light emitting element to reflect light emitted from the semiconductor light emitting element, the front opening being configured for light both directly emitted from the semiconductor light emitting element and reflected from the reflective surface to be emitted therethrough, the semiconductor light emitting element being provided in a region surrounded by the reflective surface and the front opening; and
a sealing resin provided in a space surrounded by the first supporting member and the second supporting member and configured to seal the semiconductor light emitting element;
wherein the semiconductor light emitting element has a predetermined cross-sectional shape and is oriented at a predetermined angle relative to the front opening to achieve a desired emission of light from the semiconductor light emitting device.

2. A semiconductor light emitting device of claim 1, wherein the reflective surface has a substantially semicircular shape and a surface substantially perpendicular to the main surface of the first supporting member.

3. A semiconductor light emitting device of claim 1, wherein a protrusion toward the semiconductor light emitting element is provided on the reflective surface of the second supporting member, at a back portion opposite to the front opening.

4. A semiconductor light emitting device of claim 1, further comprising a reflection layer coated on an upper surface of the sealing resin.

5. A semiconductor light emitting device of claim 1, further comprising a reflection board provided on an upper surface of the sealing resin.

6. A semiconductor light emitting device of claim 1, wherein the reflective surface has a slanted surface facing upward relative to the main surface of the first supporting member.

7. A semiconductor light emitting device of claim 6, wherein the slanted surface is provided at a back portion opposite to the front opening.

8. A semiconductor light emitting device of claim 5, wherein a protrusion toward the semiconductor light emitting element is provided on the reflection board.

9. A semiconductor light emitting device of claim 5, wherein the reflective surface has a slanted surface facing upward.

10. A semiconductor light emitting device of claim 9, wherein the reflection board is slanted.

11. The semiconductor light emitting device of claim 1, wherein the predetermined cross-sectional shape of the light emitting device is square and the predetermined angle is 45 degrees.

12. A semiconductor light emitting device, comprising:
a first supporting member having a main surface;.
a semiconductor light emitting element having a light emitting layer and provided on the main surface of the first supporting member, the light emitting layer being substantially parallel to the main surface of the first supporting member;
a second supporting member provided on the main surface of the first supporting member, the second supporting member having a reflective surface and a front opening, the reflective surface being configured to face side portions of the light emitting element to reflect light emitted from the semiconductor light emitting element, the front opening being configured for light both directly emitted from the semiconductor light emitting element and reflected from the reflective surface to be emitted therethrough, the semiconductor light emitting element being provided in a region surrounded by the reflective surface and the front opening; and
a sealing resin provided in a space surrounded by the first supporting member and the second supporting member and configured to seal the semiconductor light emitting element;
wherein an upper surface of the second supporting member is a mounting surface for mounting the semiconductor light emitting device to other apparatus to provide lighting thereto.

13. The semiconductor light emitting device of claim 12, further including connecting portions on the mounting surface of the second supporting member for connection to corresponding power supply terminals of the other apparatus when the mounting surface is mounted thereto.

14. A semiconductor light emitting device of claim 12, wherein the reflective surface has a substantially semicircular shape and a surface substantially perpendicular to the main surface of the first supporting member.

15. A semiconductor light emitting device of claim 12, wherein a protrusion toward the semiconductor light emitting element is provided on the reflective surface of the second supporting member, at a back portion opposite to the front opening.

16. A semiconductor light emitting device of claim 12, further comprising a reflection layer coated on an upper surface of the sealing resin.

17. A semiconductor light emitting device of claim 12, further comprising a reflection board provided on an upper surface of the sealing resin.

18. A semiconductor light emitting device of claim 12, wherein the reflective surface has a slanted surface facing upward relative to the main surface of the first supporting member.

19. A surface light emitting device, comprising:
a mount board;
a reflection plate provided on the mount board;.
a light guide plate provided on the reflection plate;
a diffusion plate provided on the light guide plate;
the semiconductor light emitting device of claim 1, mounted to direct light emitted thereby to the light guide plate.

20. A surface light emitting device, comprising:
a mount board;
a reflection plate provided on the mount board;
a light guide plate provided on the reflection plate;
a diffusion plate provided on the light guide plate;
the semiconductor light emitting device of claim 12, mounted to direct light emitted thereby to the light guide plate.
